(19) United States
(12) Patent Application Publication
(10) Pub. No.: US 2011/0147831 A1
(43) Pub. Date: Jun. 23, 2011

(54) METHOD FOR REPLACEMENT METAL GATE FILL

(76) Inventors: Joseph M. Steigerwald, Forest Grove, OR (US); Jack Hwang, Portland, OR (US); Chi-Hwa Tsang, Beaverton, OR (US); Michael Ollinger, Portland, OR (US); Mengcheng Lu, Portland, OR (US)

(21) Appl. No.: 12/646,678

(22) Filed: Dec. 23, 2009

(51) Int. Cl. H01L 29/78; H01L 21/28

(52) U.S. Cl. 257/330; 438/589; 257/E21.19; 257/E29.262

(57) ABSTRACT

An exemplary embodiment of a method for forming a gate for a planar-type or a finFET-type transistor comprises forming a gate trench that includes an interior surface. A first work-function metal is formed on the interior surface of the gate trench, and a low-resistivity material is deposited on the first work-function metal using a chemical vapor deposition (CVD) technique, or an atomic layer deposition (ALD) technique, or combinations thereof. Another exemplary embodiment provides that a second work-function metal is formed on the first work-function metal, and then the low-resistivity material is deposited on the first work-function metal using a chemical vapor deposition (CVD) technique, or an atomic layer deposition (ALD) technique, or combinations thereof.

### TECHNICAL FIELD

Embodiments described herein are generally directed to the field of semiconductor device fabrication and, more particularly, techniques for replacement metal gate (RMG) fill for fabricating transistors.

### BACKGROUND

Conventional techniques that utilize physical vapor deposition (PVD) for providing replacement metal gate (RMG) fill for fabricating transistors provides poor coverage of gate trench surfaces leading to voids in the gate trench and non-uniform coverage of fin sidewalls of finFET-type transistors.

### BRIEF DESCRIPTION OF THE DRAWINGS

Embodiments disclosed herein are illustrated by way of example, and not by way of limitation, in the figures of the accompanying drawings in which like reference numerals refer to similar elements and in which:

FIGS. 1A-1E depict a cross-sectional view of a PMOS transistor and an NMOS transistor at different stages of fabrication during a replacement metal gate (RMG) technique for a high-aspect ratio trench according to the subject matter disclosed herein;

FIGS. 2A-2C respectively depict cross-sectional views of an exemplary embodiment of a finFET transistor and an exemplary embodiment of a planar transistor having high-aspect ratio trenches in which a replacement metal gate (RMG) technique for a high-aspect ratio trench according to the subject matter disclosed herein can be used;

FIG. 3 is a flow diagram of a replacement metal gate (RMG) technique for a high-aspect ratio trench according to the subject matter disclosed herein; and

FIG. 4 is a diagram of an exemplary embodiment of a system in which a transistor formed using a replacement metal gate (RMG) fill technique for a high-aspect ratio trench according to the subject matter disclosed herein may be used.

It will be appreciated that for simplicity and/or clarity of illustration, elements illustrated in the figures have not necessarily been drawn to scale. For example, the dimensions of some of the elements may be exaggerated relative to other elements for clarity. Further, if considered appropriate, reference numerals have been repeated among the figures to indicate corresponding and/or analogous elements.

### DETAILED DESCRIPTION

Embodiments are described herein of replacement metal gate (RMG) fill technique for fabricating planar-type and finFET-type transistors having high-aspect ratio trenches. In the following description, numerous specific details are set forth to provide a thorough understanding of embodiments disclosed herein. One skilled in the relevant art will recognize, however, that the embodiments disclosed herein can be practiced without one or more of the specific details, or with other methods, components, materials, and so forth. In other instances, well-known structures, materials, or operations are not shown or described in detail to avoid obscuring aspects of the specification.

Reference throughout this specification to “one embodiment” or “an embodiment” means that a particular feature, structure or characteristic described in connection with the embodiment is included in at least one embodiment. Thus, appearances of the phrases “in one embodiment” or “in an embodiment” in various places throughout this specification are not necessarily all referring to the same embodiment. Furthermore, the particular features, structures or characteristics may be combined in any suitable manner in one or more embodiments. The word “exemplary” is used herein to mean “serving as an example, instance, or illustration.” Any embodiment described herein as “exemplary” is not to be construed as necessarily preferred or advantageous over other embodiments.

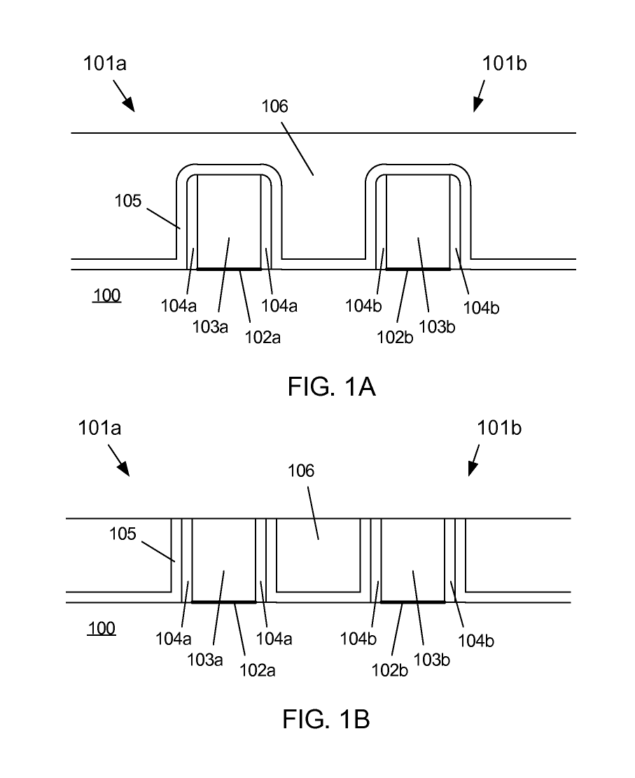

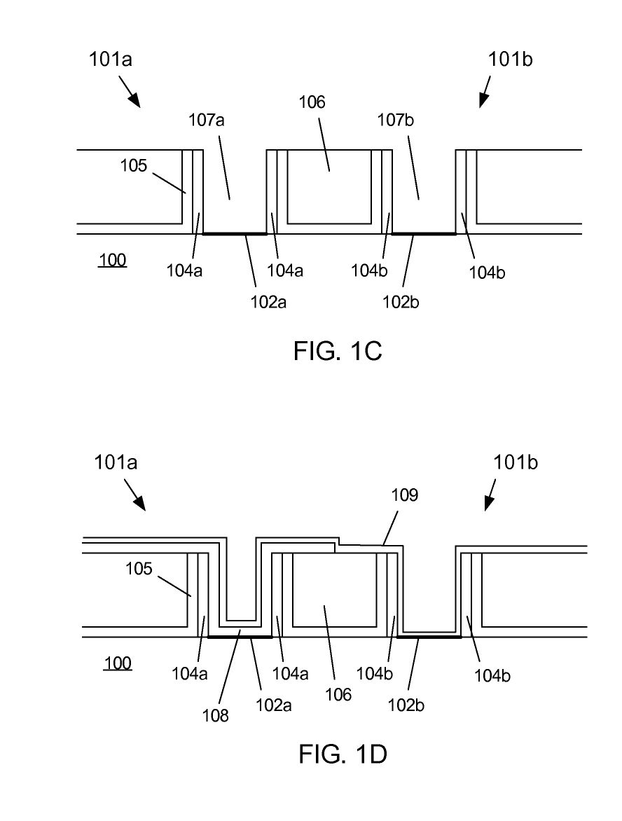

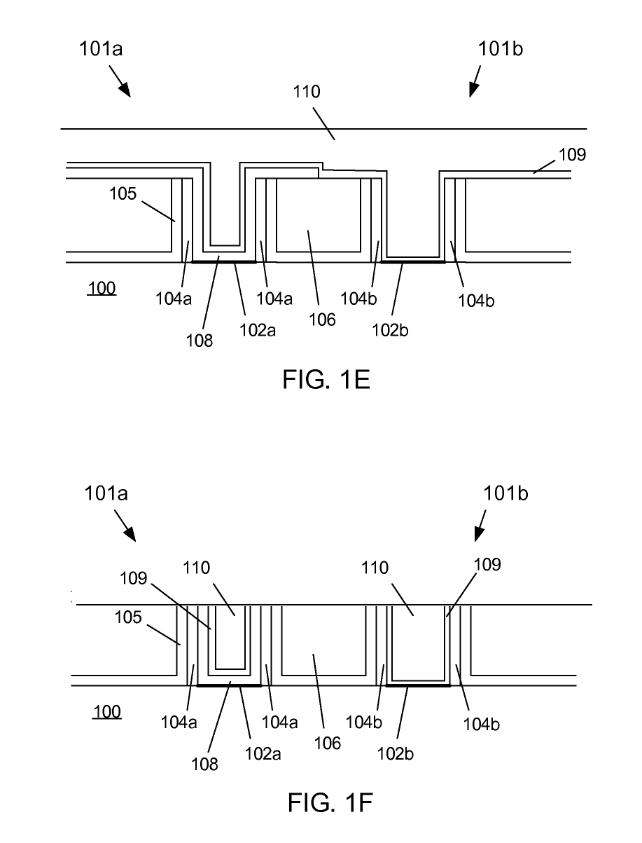

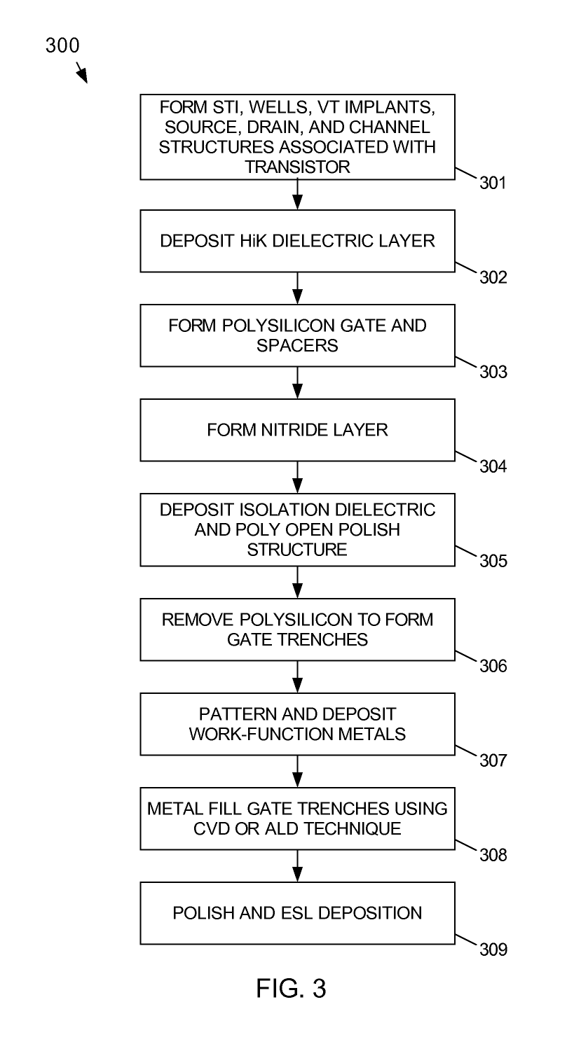

FIGS. 1A-1E depict a cross-sectional view of a planar-type PMOS transistor 101a and a planar-type NMOS transistor 101b at different stages of fabrication during a replacement metal gate (RMG) technique for a high-aspect ratio trench using a chemical vapor deposition (CVD) step or an atomic layer deposition (ALD) step according to the subject matter disclosed herein. FIG. 3 is a flow diagram of a replacement metal gate (RMG) technique 300 for a high-aspect ratio trench according to the subject matter disclosed herein.

FIG. 1A, in particular, depicts planar-type MOS transistors at a stage of fabrication in which shallow trench isolation (STI), wells and voltage threshold (VT) implants have already taken place (step 301 in FIG. 3). Transistors 101a, 101b each comprise a high-K (HiK) gate dielectric layer 102a, 102b, such as, but not limited to, hafnium silicate (HfSiO₄), zirconium silicate (ZrSiO₄), hafnium dioxide (HfO₂), or zirconium dioxide (ZrO₂), or combinations thereof, that has been deposited on a substrate 100, such as by an atomic layer deposition (ALD) technique. (step 302) Other possible HiK materials include, but are not limited to, tantalum pentoxide (Ta₂O₅), aluminum oxide (Al₂O₃), or lanthanum oxide (La₂O₃), or combinations thereof. Polysilicon gate 103a, 103b is formed on gate dielectric layer 102a, 102b (step 303). Additionally, polysilicon gates 103a, 103b are each surrounded by dielectric spacers 104a, 104b, which have been formed (step 303). A dielectric layer 105 is formed on both transistor gate structures (step 304). Possible materials for dielectric layer 105 include, but are not limited to, silicon nitride (Si₃N₄), silicon carbide (SiC), or boron nitride (BN), or combinations thereof. An isolation dielectric 106 is formed on both transistor gate structures and nitride layer 105 (step 305). It should be understood that source, drain and channel structures associated with planar-type MOS transistors that are below the gate dielectric layers 102a, 102b are not shown in FIGS. 1A-1E for clarity.

In FIG. 1B, a polishing technique, such as, but not limited to, a poly opening polish, such as a chemical mechanical polish (CMP), is applied to the structure depicted in FIG. 1A to planarize the structure and expose the polysilicon gates 103a, 103b (step 305).

In FIG. 1C, polysilicon gates 103a, 103b are removed leaving open gate trenches 107a, 107b (step 306). Suitable technique for removing polysilicon gates 103a, 103b include a wet etch or a dry etch. Gate trenches 107a, 107b have a high-aspect ratio (depth to opening ratio) in the range of between about 1:1 and about 5:1. It should be understood that the subject matter disclosed herein is suitable for high-aspect-ratio gate trenches that have an aspect ratio that is greater than about 5:1.

In FIG. 1D, different work-function metals are patterned, such as by masking, and deposited using, for example, CVD or ALD, in gate trenches 107a, 107b and the transistor structures (step 307). The particular work-function metal used depends on whether the transistor will be a PMOS transistor or an NMOS transistor. For transistor 101a, which for this exemplary structure will be a PMOS transistor, a first work-function metal 108 is deposited on HiK dielectric 102a in gate trench 107a, on the sidewalls of gate trench 107a and surrounding the opening of gate trench 107a. Possible work-function metals for work-function metal 108 include, but are not limited to, ruthenium, antimony, gold, palladium, nickel, cobalt, osmium, titanium nitride, tantalum nitride, tellurium, iridium, and platinum, or combinations thereof. For transistor 101b, which for this exemplary structure will be an NMOS transistor, a second work-function metal 109 is deposited on HiK dielectric 102b in gate trench 107b, the sidewalls of gate trench 107b and surrounding the opening of gate trench 107b. Possible work-function metals for work-function metal 109 include, but are not limited to, lanthanum, magnesium, thallium, hafnium, aluminum, manganese, tantalum, silver, or zirconium, or combinations thereof. Additionally, second work-function metal 109 is deposited on first work-function metal 107 in gate trench 107a, on the sidewalls of gate trench 107a and surrounding the opening of gate trench 107a.

In FIG. 1E, a low-resistivity metal film 110, such as tungsten (W), cobalt (Co), or titanium nitride (TiN), molybdenum, ruthenium, nickel or combinations thereof, is deposited on work-functions metals 108 and 109 using either a chemical vapor deposition (CVD) or an atomic layer deposition (ALD) (step 308). Possible low-resistivity materials include, but are not limited to, any metal that can be deposited using a CVD or an ALD technique tungsten (W), cobalt (Co), titanium nitride (TiN), tantalum nitride (TaN), aluminum (Al), nickel, (Ni), titanium (Ti), or molybdenum, ruthenium, nickel, tantalum (Ta), or combinations thereof. Thus, according to the subject matter disclosed herein, the conformal nature of a CVD or an ALD deposition provides a complete fill of the gate trench without voids in contrast to when a conventional metallization technique, such as physical vapor deposition (PVD) techniques, is used for a replacement metal gate (RMG) technique. Moreover, the RMG technique disclosed herein completely fills a gate trench even when the gate trench is reentrant, that is, when the width of a cross-section of the opening of the gate trench is smaller than a width of a cross-section of the gate trench further into the gate trench.

In FIG. 1F, polish techniques and Etch Stop Layer (ESL) deposition techniques have been performed and completed (step 309).

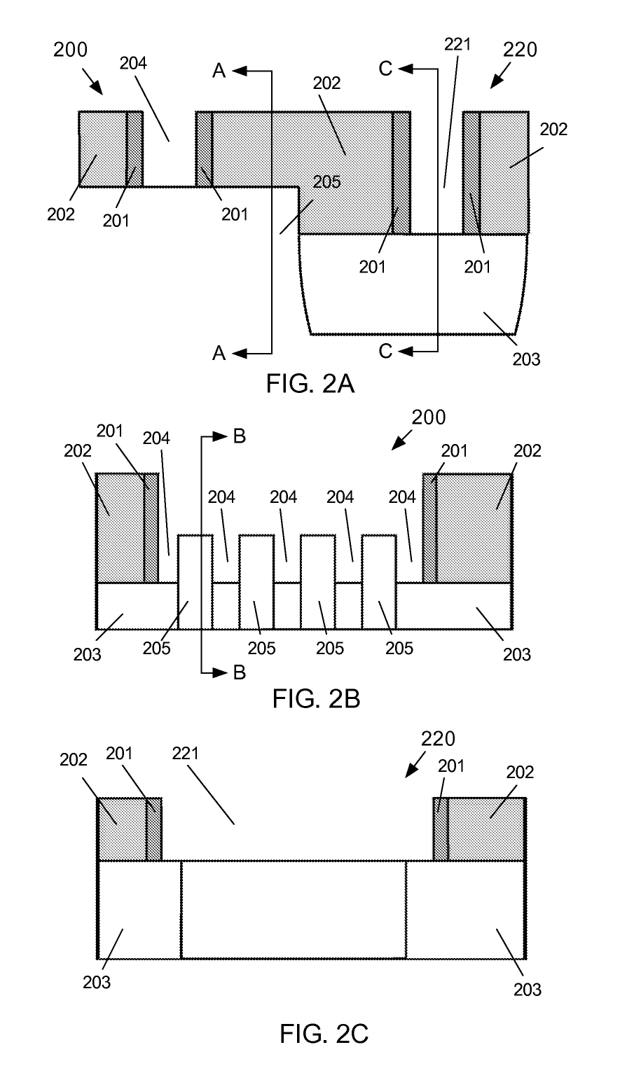

According to the subject matter disclosed herein, one exemplary embodiment of a replacement metal gate (RMG) fill technique is suitable for fabricating finFET-type transistors. FIGS. 2A-2C respectively depict cross-sectional views of an exemplary embodiment of a finFET transistor 200 and an exemplary embodiment of a planar transistor 220 having high-aspect ratio trenches in which a replacement metal gate (RMG) technique for a high-aspect ratio trench according to the subject matter disclosed herein can be used. More specifically, FIG. 2A depicts a cross-section view of finFET transistor 200 taken along line B-B in FIG. 2B. FIG. 2B depicts a cross-sectional view of finFET transistor 200 taken along line A-A in FIG. 2A. FIG. 2C depicts a cross-sectional view of planar transistor 220 taken along line C-C in FIG. 2A. The configuration of transistors 200 and 220 includes spacers 201, interlayer dielectric layers 202 and shallow trench isolation (STI) region 203. Transistor 200 includes a plurality of high-aspect-ratio gate trenches 204 associated with fins 205. Transistor 220 includes one high-aspect ratio gate trench 221. It should be understood that finFET transistor 200 could have any number of gate trenches. It should also be understood that not all of the structure for transistors 200 and 220 is shown in FIGS. 2A-2C.

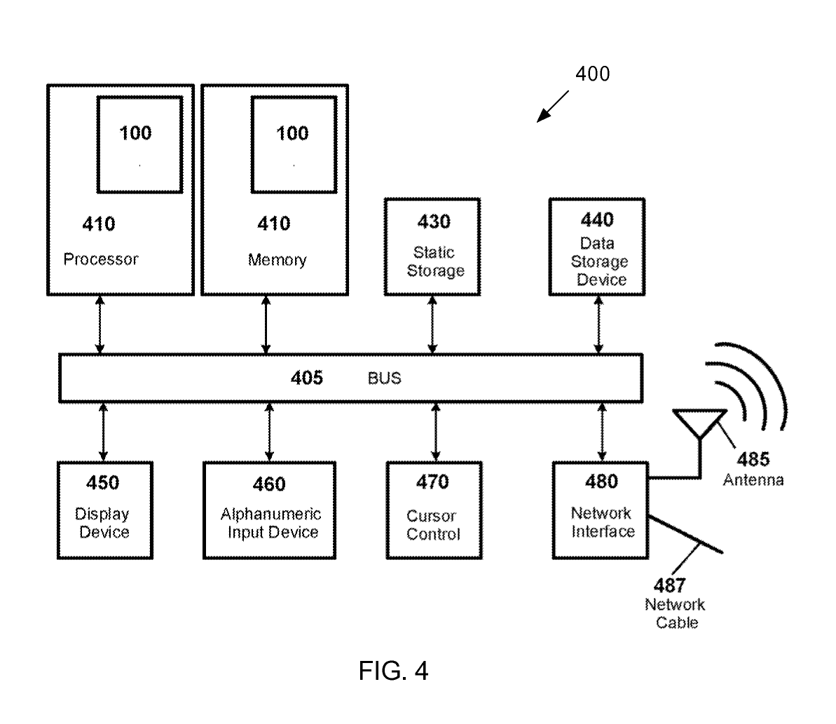

FIG. 4 is a diagram of an exemplary embodiment of a system in which a transistor 100 formed using a replacement metal gate (RMG) fill technique for a high-aspect ratio trench according to the subject matter disclosed herein may be used. System 400 is intended to represent a range of electronic systems (either wired or wireless) including, for example, desktop computer systems, laptop computer systems, personal computers (PC), wireless telephones, personal digital assistants (PDA) including cellular-enabled PDAs, set top boxes, pocket PCs, tablet PCs, DVD players, or servers, but is not limited to, these examples and may comprise other electronic systems. Alternative electronic systems may comprise more, fewer and/or different components.

In one exemplary embodiment, electronic system 400 comprises a transistor 100 formed using a replacement metal gate (RMG) fill technique according to the subject matter disclosed herein. In another exemplary embodiment, a transistor 100 formed using a replacement metal gate (RMG) fill technique according to the subject matter disclosed herein is part of an electronic system's processor 410 or memory 420. Electronic system 400 may comprise a processor 410 and memory 420 coupled with the processor 410, wherein the processor 410 or the memory 420, or combinations thereof, comprise a transistor 100 formed using a replacement metal gate (RMG) fill technique according to the subject matter disclosed herein.

Electronic system 400 may comprise bus 405 or other communication device to communicate information, and processor 410 coupled to bus 405 that may process information. While electronic system 400 may be illustrated with a single processor, system 400 may comprise multiple processors and/or co-processors. In an exemplary embodiment, processor 410 comprising a floating gate device 100 as described herein. System 400 may also comprise random access memory (RAM) or other storage device 420 (may be referred to as memory), coupled to bus 405 and may store information and instructions that may be executed by processor 410.

Memory 420 may also be used to store temporary variables or other intermediate information during execution of instructions by processor 410. Memory 420 is a flash memory device in one exemplary embodiment. In another exemplary embodiment, memory 420 comprises a transistor 100 formed using a replacement metal gate (RMG) fill technique according to the subject matter disclosed herein.

System 400 may also comprise read only memory (ROM) and/or other static storage device 430 coupled to bus 405 that may store static information and instructions for processor 410. Data storage device 440 may be coupled to bus 405 to store information and instructions. Data storage device 440, such as a magnetic disk or optical disc and corresponding drive, may be coupled with electronic system 400.

Electronic system 400 may also be coupled via bus 405 to display device 450, such as a cathode ray tube (CRT) or liquid crystal display (LCD), to display information to a user. Alphanumeric input device 460, including alphanumeric and other keys, may be coupled to bus 405 to communicate information and command selections to processor 410. Another type of user input device is cursor control 470, such as a mouse, a trackball, or cursor direction keys to communicate information and command selections to processor 410 and to control cursor movement on display 450.

Electronic system 400 further may comprise one or more network interfaces 480 to provide access to network, such as a local area network. Network interface 480 may comprise, for example, a wireless network interface having antenna 485, which may represent one or more antennae. Network interface 480 may also comprise, for example, a wired network interface to communicate with remote devices via network cable 487, which may be, for example, an Ethernet cable, a coaxial cable, a fiber optic cable, a serial cable, or a parallel cable.

In one exemplary embodiment, network interface 480 may provide access to a local area network, for example, by conforming to an Institute of Electrical and Electronics Engineers (IEEE) standard such as IEEE 802.11b and/or IEEE 802.11g standards, and/or the wireless network interface may provide access to a personal area network, for example, by conforming to Bluetooth standards. Other wireless network interfaces and/or protocols could also be supported.

IEEE 802.11b corresponds to IEEE Std. 802.11b-1999 entitled “Local and Metropolitan Area Networks, Part 11: Wireless LAN Medium Access Control (MAC) and Physical Layer (PHY) Specifications: Higher-Speed Physical Layer Extension in the 2.4 GHz Band,” approved Sep. 16, 1999, as well as related documents. IEEE 802.11g corresponds to IEEE Std. 802.11g-2003 entitled “Local and Metropolitan Area Networks, Part 11: Wireless LAN Medium Access Control (MAC) and Physical Layer (PHY) Specifications, Amendment 4: Further Higher Rate Extension in the 2.4 GHz Band,” approved Jun. 27, 2003, as well as related documents. Bluetooth protocols are described in “Specification of the Bluetooth System: Core, Version 1.1,” published Feb. 22, 2001, by the Bluetooth Special Interest Group, Inc. Previous or subsequent versions of the Bluetooth standard may also be supported.

In addition to, or instead of, communication via wireless LAN standards, network interface(s) 480 may provide wireless communications using, for example, Time Division, Multiple Access (TDMA) protocols, Global System for Mobile Communications (GSM) protocols, Code Division, Multiple Access (CDMA) protocols, and/or any other type of wireless communications protocol.

In an embodiment, a system 400 comprises one or more omnidirectional antennae 485, which may refer to an antenna that is at least partially omnidirectional and/or substantially omnidirectional, and a processor 410 coupled to communicate via the antennae.

The above description of illustrated embodiments, including what is described in the Abstract, is not intended to be exhaustive or to limit to the precise forms disclosed. While specific embodiments and examples are described herein for illustrative purposes, various equivalent modifications are possible within the scope of this description, as those skilled in the relevant art will recognize. These modifications can be made in light of the above detailed description. The terms used in the following claims should not be construed to limit the scope to the specific embodiments disclosed in the specification and the claims. Rather, the scope of the embodiments disclosed herein is to be determined by the following claims, which are to be construed in accordance with established doctrines of claim interpretation.

What is claimed is:

1. A method for forming a gate for a transistor, the method comprising:
providing a gate trench, the gate trench comprising an interior surface of the gate trench; and
forming a first work-function metal on the interior surface of the gate trench; and
depositing a low-resistivity material on the first work-function metal using a chemical vapor deposition (CVD) technique, or an atomic layer deposition (ALD) technique, or combinations thereof.

2. The method according to claim 1, wherein forming the first work-function metal on the interior surface of the gate trench further comprises forming a second work-function metal on the first work-function metal, the second work-function metal having a different work function than the work function of the first work-function metal; and
wherein depositing the low-resistivity material comprising depositing the low-resistivity material on the second work-function metal using a chemical vapor deposition (CVD) technique, or a atomic layer deposition (ALD) technique, or combinations thereof.

3. The method according to claim 2, wherein providing the gate trench comprises:
forming a polysilicon gate structure, the polysilicon gate structure comprising at least one exterior sidewall;
forming a spacer on the at least one exterior sidewall; and
removing the polysilicon gate structure.

4. The method according to claim 3, wherein the low-resistivity material comprises a metal-film material.

5. The method according to claim 4, wherein the metal-film material comprises tungsten, cobalt or titanium nitride, or combinations thereof.

6. The method according to claim 5, wherein the gate trench has a ratio of a depth of the gate trench to a width of the gate trench of greater than about 1:1.

7. The method according to claim 6, wherein the gate trench comprises part of a finFET transistor.

8. The method according to claim 6, wherein the gate trench comprises part of a planar transistor.

9. The method according to claim 1, wherein providing the gate trench comprises:
forming a polysilicon gate structure, the polysilicon gate structure comprising at least one exterior sidewall;
forming a spacer on the at least one exterior sidewall; and
removing the polysilicon gate structure.

10. The method according to claim 9, wherein the low-resistivity material comprises a metal-film material.

11. The method according to claim 10, wherein the metal-film material comprises tungsten, cobalt or titanium nitride, or combinations thereof.

12. The method according to claim 11, wherein the gate trench has a ratio of a depth of the gate trench to a width of the gate trench of greater than about 1:1.

13. A semiconductor device, comprising:
a gate trench, the gate trench comprising an interior surface of the gate trench; and
a first work-function metal formed on the interior surface of the gate trench; and
a low-resistivity material formed on the first work-function metal that includes at least one metal selected from the group consisting of tungsten, cobalt, and titanium nitride.

14. The semiconductor device according to claim 13, further comprising a second work-function metal formed on the first work-function metal, the second work-function metal having a different work function than the work function of the first work-function metal; and
wherein the low-resistivity material is deposited on the second work-function metal using a chemical vapor deposition (CVD) technique, or an atomic layer deposition (ALD) technique, or combinations thereof.

15. The semiconductor device to claim 14, wherein the low-resistivity material comprises a metal-film material.

16. The semiconductor device according to claim 15, wherein the gate trench has a ratio of a depth of the gate trench to a width of the gate trench of greater than about 1:1.

17. The semiconductor device according to claim 16, wherein the gate trench comprises part of a finFET transistor.

18. The semiconductor device according to claim 16, wherein the gate trench comprises part of a planar transistor.
